(19) United States
(12) Patent Application Publication
(10) Pub. No.: US 2020/0332064 A1
(43) Pub. Date: Oct. 22, 2020

(54) ANISOTROPIC HEAT-CONDUCTIVE SHEET HAVING SELF-ADHESIVENESS

(71) Applicant: Shin-Etsu Chemical Co., Ltd., Tokyo (JP)

(72) Inventors: Yoshinori TAKAMATSU, Annaka-shi (JP); Kentaro BAMBA, Annaka-shi (JP); Kazuaki SUMITA, Annaka-shi (JP)

(73) Assignee: Shin-Etsu Chemical Co., Ltd., Tokyo (JP)

(21) Appl. No.: 16/835,699

(22) Filed: Mar. 31, 2020

(30) Foreign Application Priority Data
Apr. 16, 2019 (JP) 2019-077929

(51) Int. Cl. C08G 77/12; C09J 9/00; C09J 11/06; H01L 23/373

(52) U.S. Cl. CPC C08G 77/12; C09J 9/00; C09J 2203/326; H01L 23/3737; C09J 11/06

(57) ABSTRACT

An anisotropic heat-conductive sheet having self-adhesiveness is defined as comprising a heat-conductive layer of a cured resin composition comprising (A) a fibrous heat-conductive filler and (B) a thermosetting organopolysiloxane composition, the heat-conductive sheet having a penetration of at least 30. The heat-conductive sheet has many advantages including reliability, thermal conductivity, adhesiveness, and elongation.

### CROSS-REFERENCE TO RELATED APPLICATION

This non-provisional application claims priority under 35 U.S.C. § 119(a) on Patent Application No. 2019-077929 filed in Japan on Apr. 16, 2019, the entire contents of which are hereby incorporated by reference.

### TECHNICAL FIELD

This invention relates to an anisotropic heat-conductive sheet having self-adhesiveness.

### BACKGROUND ART

Nowadays, materials used in automobiles, aircraft, and electronic parts are desired to improve their performance from various aspects. Especially, the materials used for dissipating or insulating the heat generated by electronic parts and equipment are desired to have ever growing performance. Among others, heat-conductive sheets having high thermal conductivity, ease of handling and high reliability are desirably modified so as to find use in automobiles.

Of such heat-conductive sheets, Patent Document 1 discloses a low hardness heat-dissipating sheet of a resin with heavy loading of aluminum nitride and aluminum oxide. With this technique, the inorganic fillers must be heavily loaded to gain a high thermal conductivity, but the sheet loses elongation, adhesiveness, and reliability. The hardness is reduced by adding a large amount of an organic oil that is not involved in curing, which raises a problem of oil bleeding.

Patent Documents 2 to 4 disclose a method for producing a heat-conductive sheet by loading a resin with an anisotropic high heat-conductive filler in certain orientation, sheeting and slicing. These methods use resin compositions having a thermal conductivity of several tens of W/mK. Since the slicing step is included, the resins which can be used as the binder are limited to rubber-like resins having relatively high hardness, leading to increased elongation and interfacial thermal resistance. As a result of slicing, the material is given brittleness. In Patent Document 4, an adhesive layer is applied to the sheet after slicing, to bring about another problem of interfacial thermal resistance.

Patent Document 5 discloses a heat-conductive sheet of an adhesive resin loaded with an inorganic filler. While this technique intends to prepare an adhesive heat-conductive sheet, the amount of the inorganic filler loaded is limited in order to maintain adhesiveness. The limited amount of filler is difficult to achieve a high thermal conductivity.

It would be desirable to have a heat-conductive material having high reliability, thermal conductivity, adhesiveness, and elongation.

### CITATION LIST

Patent Document 1: JP-A 2010-235842

Patent Document 2: JP-A 2012-015273

Patent Document 3: JP-A 2015-216387

Patent Document 4: JP-A 2007-283509

Patent Document 5: JP-A 2008-277768

### SUMMARY OF INVENTION

An object of the invention is to provide an anisotropic heat-conductive sheet having high reliability, thermal conductivity, adhesiveness, and elongation.

The inventors have found that an anisotropic heat-conductive sheet comprising a thermosetting organopolysiloxane composition and a fibrous heat-conductive filler oriented in a certain direction and having a penetration within the specific range exhibits high reliability, thermal conductivity, adhesiveness, and elongation.

In one aspect, the invention provides an anisotropic heat-conductive sheet having self-adhesiveness, comprising at least one heat-conductive layer of a cured product of a resin composition comprising (A) a fibrous heat-conductive filler and (B) a thermosetting organopolysiloxane composition, the heat-conductive sheet having a penetration of at least 30.

Preferably, all or some fibers of the heat-conductive filler (A) are oriented in one direction in the heat-conductive sheet. More preferably, fibers of the heat-conductive filler (A) are oriented in thickness direction of the heat-conductive sheet.

In one preferred embodiment, the thermosetting organopolysiloxane composition (B) is an addition reaction curable organopolysiloxane composition comprising (B-1) an organopolysiloxane having at least two alkenyl groups per molecule, (B-2) an organohydrogenpolysiloxane having at least two silicon-bonded hydrogen atoms per molecule, and (B-3) a platinum-based catalyst.

Preferably, after 1,000 cycles of a thermal cycling test of holding at −55° C. for 30 minutes and heating at 150° C. for 30 minutes, the anisotropic heat-conductive sheet has a penetration corresponding to 80 to 120% of the initial penetration of the sheet before the cycling test.

Preferably, the anisotropic heat-conductive sheet has a surface tack of at least No. 4 in a ball tack test using an inclination board of angle 30° according to JIS Z-0237: 2009. More preferably, after 1,000 cycles of a thermal cycling test of holding at −55° C. for 30 minutes and heating at 150° C. for 30 minutes, the anisotropic heat-conductive sheet has a surface tack of at least No. 4 in the ball tack test.

### Advantageous Effects of Invention

The anisotropic heat-conductive sheet is fully improved in reliability, thermal conductivity, adhesiveness, and elongation.

### BRIEF DESCRIPTION OF DRAWINGS

FIG. 1 is a conceptual diagram for illustrating the state of magnetic flux density of a bulk superconductor magnet.

FIG. 2 is a side view of a sheet-shaped resin compact.

FIG. 3 is a schematic elevational view of one exemplary manufacturing apparatus used in the invention.

FIG. 4 schematically illustrates the orientation under a magnetic field.

### DESCRIPTION OF PREFERRED EMBODIMENTS

As used herein, the notation (Cn-Cm) means a group containing from n to m carbon atoms per group. The term “adhesive” or “adhesiveness” refers to pressure-sensitive adhesive or adhesiveness unless otherwise stated.

The invention is directed to an anisotropic heat-conductive sheet having at least one heat-conductive layer comprising (A) a fibrous heat-conductive filler and (B) a thermosetting organopolysiloxane composition. The anisotropic heat-conductive sheet exhibits adhesiveness by itself, i.e., self-adhesiveness even though no adhesive layer is separately attached to the sheet surface.

### (A) Fibrous Heat-Conductive Filler

The filler which is added to the resin composition is a fibrous heat-conductive filler. In view of adhesiveness, at least some of fibers of the heat-conductive filler are preferably oriented in one direction. More preferably, at least 30% by weight of the fibers based on the total amount of the filler are oriented in one direction. The thermal conductivity of the layer is improved by controlling the orientation of fibers in one direction. By orienting the heat-conductive filler fibers in a thickness direction of the sheet, the footprint or area of filler fibers on the sheet surface is reduced. Then, the adhesiveness of the sheet is improved or maintained and the elongation is increased.

Examples of the fibrous filler include cellulose nanofibers, carbon fibers, alumina fibers, aluminum nitride whiskers, and metal nanowires. Of these, carbon fibers are preferred in view of thermal conductivity. Flake fillers and plate fillers having a high aspect ratio are also encompassed in the fibrous filler.

Specifically, pitch carbon fibers are preferred, with pitch carbon fibers having a thermal conductivity in the axial direction of at least 500 W/mK being more preferred. The length of the carbon fibers is preferably at least 50 μm in view of thermal conductivity. The amount of the filler loaded is preferably 10 to 300 parts by weight per 100 parts by weight of the thermosetting organopolysiloxane composition (B). From the aspects of self-adhesiveness and thermal conductivity, the amount of the filler is more preferably 20 to 200 parts by weight. Less than 10 parts of the filler may fail to achieve satisfactory heat conduction whereas more than 300 parts of the filler may detract from self-adhesiveness. Also, a nonfibrous filler such as spherical silica may be used in combination for the purpose of enhancing the strength of the cured resin.

### (B) Thermosetting Organopolysiloxane Composition

The thermosetting organopolysiloxane composition used for the heat-conductive sheet is preferably a resin composition which cures into a rubber- or gel-like product. The resin composition which cures into a gel-like product is more preferred from the aspects of development of self-adhesiveness, elongation, and heat resistance. The gel-like cured product should preferably have a penetration of at least 30, more preferably 40 to 90. As used herein, the “penetration” is measured as a distance of penetration by the consistency test method according to JIS K-2220: 2013, using a ¼ cone under a total load of 9.38 g.

The thermosetting organopolysiloxane composition is preferably an addition reaction curable organopolysiloxane composition comprising:

(B-1) an organopolysiloxane having at least two alkenyl groups per molecule,

(B-2) an organohydrogenpolysiloxane having at least two silicon-bonded hydrogen atoms per molecule, and

(B-3) a platinum-based catalyst.

### (B-1) Alkenyl-Containing Organopolysiloxane

The alkenyl-containing organopolysiloxane as component (B-1) serves as the base polymer of the organopolysiloxane composition which cures into a heat-conductive sheet. Component (B-1) is preferably a generally linear diorganopolysiloxane (or diorganopolysiloxane which may partially contain a branched structure) having the average compositional formula (1).

R¹ₐSiO_{(4-a)/2} (1)

Herein R¹ is independently a substituted or unsubstituted C₁-C₁₂ monovalent hydrocarbon group, with the proviso that at least two alkenyl groups are included per molecule, and “a” is a positive number of 1.8 to 2.2, preferably 1.95 to 2.05.

The organopolysiloxane (B-1) has at least two, preferably about 3 to about 100, more preferably about 3 to about 50 silicon-bonded alkenyl groups per molecule. As long as at least two silicon-bonded alkenyl groups are included, the composition comprising that organopolysiloxane is curable. The silicon-bonded alkenyl group is preferably vinyl. The alkenyl group may be attached to the end of the molecular chain and/or side chains from the molecular chain. At least one alkenyl group is preferably attached to the silicon atom at the end of the molecular chain.

In formula (1), R¹ is independently a substituted or unsubstituted monovalent hydrocarbon group of 1 to 12 carbon atoms, preferably 1 to 10 carbon atoms, and more preferably 1 to 6 carbon atoms.

Examples of R¹ include alkyl groups such as methyl, ethyl, propyl, isopropyl, butyl, isobutyl, tert-butyl, pentyl, neopentyl, hexyl, heptyl, octyl, nonyl, decyl, and dodecyl, cycloalkyl groups such as cyclopentyl, cyclohexyl, and cycloheptyl, aryl groups such as phenyl, tolyl, xylyl, naphthyl, and biphenylyl, aralkyl groups such as benzyl, phenylethyl, phenylpropyl, and methylbenzyl, alkenyl groups such as vinyl, allyl, butenyl, pentenyl, and hexenyl, and substituted forms of the foregoing groups in which some or all of the carbon-bonded hydrogen atoms are substituted by halogen atoms (e.g., fluorine, chlorine and bromine), cyano or the like, such as chloromethyl, 2-bromoethyl, 3-chloropropyl, 3,3,3-trifloropropyl, chlorophenyl, fluorophenyl, cyanoethyl and 3,3,4,4,5,5,6,6,6-nonafluorohexyl. Preferred are substituted or unsubstituted C₁-C₃ alkyl groups such as methyl, ethyl, propyl, chloromethyl, bromoethyl, 3,3,3-trifluoropropyl, and cyanoethyl, substituted or unsubstituted phenyl groups such as phenyl, chlorophenyl, and fluorophenyl, and alkenyl groups such as vinyl and allyl.

The organopolysiloxane (B-1) may be used alone or in combination of two or more organopolysiloxanes having different kinematic viscosity, molecular structure or the like.

### (B-2) Organohydrogenpolysiloxane

Component (B-2) serves as a crosslinker for component (B-1). Component (B-2) is an organohydrogenpolysiloxane having at least two, preferably about 2 to about 200, more preferably about 3 to about 100 silicon-bonded hydrogen atoms (i.e., hydrosilyl groups) per molecule.

The organohydrogenpolysiloxane contains silicon-bonded organic groups, which include substituted or unsubstituted monovalent hydrocarbon groups free of aliphatic unsaturation. Examples include substituted or unsubstituted monovalent hydrocarbon groups, as exemplified above for the silicon-bonded substituted or unsubstituted monovalent hydrocarbon group in component (B-1), excluding the aliphatic unsaturated groups such as alkenyl groups. Of these, methyl is preferred for ease of synthesis and cost.

The structure of the organohydrogenpolysiloxane (B-2) is not particularly limited. It may have a linear, branched, cyclic or three-dimensional network structure, preferably linear structure.

The organohydrogenpolysiloxane typically has a degree of polymerization (or number of silicon atoms) of about 2 to about 200, preferably about 2 to about 100, and more preferably about 2 to about 50.

Suitable examples of the organohydrogenpolysiloxane include 1,1,3,3-tetramethyldisiloxane, 1,3,5,7-tetramethylcyclotetrasiloxane, tris(hydrogendimethylsiloxy)methylsilane, tris(hydrogendimethylsiloxy)phenylsilane, methylhydrogencyclopolysiloxane, methylhydrogensiloxane/dimethylsiloxane cyclic copolymers, both end trimethylsiloxy-blocked methylhydrogenpolysiloxane, both end trimethylsiloxy-blocked dimethylsiloxane/methylhydrogensiloxane copolymers, both end trimethylsiloxy-blocked dimethylsiloxane/methylhydrogensiloxane/methylphenylsiloxane copolymers, both end dimethylhydrogensiloxy-blocked dimethylpolysiloxane, both end dimethylhydrogensiloxy-blocked dimethylsiloxane/methylhydrogensiloxane copolymers, both end dimethylhydrogensiloxy-blocked dimethylsiloxane/methylphenylsiloxane copolymers, both end dimethylhydrogensiloxy-blocked methylphenylpolysiloxane, copolymers consisting of (CH₃)₂HSiO_{1/2} units, (CH₃)₃SiO_{1/2} units and SiO_{4/2} units, copolymers consisting of (CH₃)₂HSiO_{1/2} units and SiO_{4/2} units, and copolymers consisting of (CH₃)₂HSiO_{1/2} units, SiO_{4/2} units and (C₆H₅)₃SiO_{1/2} units. The organohydrogenpolysiloxane (B-2) may be used alone or in admixture.

The organohydrogenpolysiloxane is preferably blended in an amount to give 0.5 to 5.0 moles, more preferably 0.8 to 4.0 moles of hydrosilyl groups per mole of alkenyl groups in component (B-1). When the amount of hydrosilyl groups in the organohydrogenpolysiloxane is at least 0.5 mole per mole of alkenyl groups in component (B-1), the organopolysiloxane composition fully cures into a cured product having so high strength that shaped compacts or composites thereof are easy to handle.

### (B-3) Platinum-Based Catalyst

The platinum-based catalyst as component (B-3) is a catalyst component which is added to promote hydrosilylation or addition reaction between alkenyl groups in component (B-1) and hydrosilyl groups in component (B-2) for thereby converting the organopolysiloxane composition to a crosslinked or cured product having a three-dimensional network structure.

The platinum-based catalyst may be selected as appropriate from well-known platinum-based catalysts commonly used in hydrosilylation or addition reaction. Suitable catalysts include platinum group metal catalysts such as platinum group metals and platinum group metal compounds, examples of which include platinum group metals alone such as platinum (including platinum black), rhodium and palladium; platinum chlorides, chloroplatinic acids and chloroplatinates such as H₂PtCl₄.xH₂O, H₂PtCl₆.xH₂O, NaHPtCl₆.xH₂O, KHPtCl₆.xH₂O, Na₂PtCl₆.xH₂O, K₂PtCl₄.xH₂O, PtCl₄.xH₂O, PtCl₂, and Na₂HPtCl₄.xH₂O, wherein x is an integer of 0 to 6, preferably 0 or 6; alcohol-modified chloroplatinic acids; chloroplatinic acid-olefin complexes; supported catalysts comprising platinum group metals such as platinum black and palladium on supports of alumina, silica, and carbon; rhodium-olefin complexes; chlorotris(triphenylphosphine)rhodium (Wilkinson's catalyst); and complexes of platinum chlorides, chloroplatinic acids, and chloroplatinates with vinyl-containing siloxanes. The platinum group metal catalyst may be used alone or in admixture.

The platinum-based catalyst (B-3) is blended in an effective amount for curing the organopolysiloxane composition, typically in an amount to give 0.1 to 1,000 ppm, preferably 0.5 to 500 ppm of platinum group metal element based on the weight of component (B-1).

Besides components (B-1) to (B-3), optional components such as reaction inhibitors, adhesive aids, and polyorganosiloxanes which are not involved in curing may be added to the addition curable organopolysiloxane composition used as the thermosetting organopolysiloxane composition (B).

The organopolysiloxane composition (B) is preferably liquid at 25° C. More preferably it has a viscosity of 0.01 to 50 Pa·s as measured by a rotational viscometer according to JIS K-7117-1: 1999.

The organopolysiloxane composition (B) may be prepared, for example, by intimately mixing components (B-1) to (B-3) on a kneading device such as a gate mixer, planetary mixer or planetary centrifugal mixer. Alternatively, commercially available silicone gel or rubber compositions may be used as component (B).

In connection with the resin composition containing components (A) and (B), the method for orienting the fibrous heat-conductive filler (A) in one direction in the resin is not particularly limited. The method may be, for example, by orienting component (A) in the resin composition under an applied magnetic field, or by impregnating a bundle or cloth of carbon fibers used as component (A) with a gel-like resin composition used as component (B) and slicing the impregnated product.

In the method for orienting component (A) under a magnetic field, a magnetic field is applied from a superconducting coil magnet or bulk superconductor magnet. Under the action of the magnetic field, filler fibers are preferably oriented in the sheet with the aid of ultrasonic vibration. In view of ease of production, a bulk superconductor magnet is preferably used as a magnetic field source. The method for orientation of the filler under a magnetic field is described below in detail.

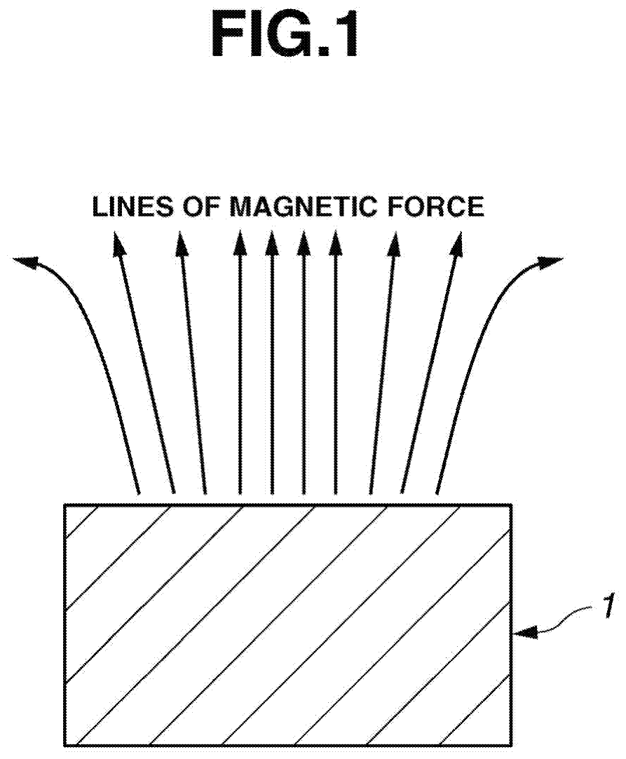

The bulk superconductor magnet is obtained by magnetizing a superconductor in a magnetic field of a superconducting coil and used as a magnetic pole. Once magnetized, the magnet semipermanently maintains a strong magnetic flux density in the cryostatic state. FIG. 1 is a conceptual diagram of a bulk superconductor magnet 1 producing lines of magnetic force, illustrating the state of magnetic flux density. Suitable magnetizing methods include pulse magnetizing and magnetizing by a superconducting coil magnet.

Magnetizing by a superconducting coil magnet is preferred for the magnitude of an available magnetic flux density. The superconducting coil magnet used for magnetization preferably has a magnetic flux density of at least 6 T. If the magnetic flux density is less than 6 T, the bulk superconductor magnet magnetized thereby may have an insufficient magnetic flux density.

Although the superconductor used for the bulk superconductor magnet is not particularly limited, RE-Ba—Cu—O (wherein RE is at least one element selected from Y, Sm, Nd, Yb, La, Gd, Eu, and Er), MgB₂, NbSn₃ and iron based superconductors are preferred. The RE-Ba—Cu—O based superconductors are more preferred for cost, simple preparation, and the magnitude of a magnetic flux density.

The shape and size of the bulk superconductor magnet are not particularly limited. From the aspect of magnetic field strength, a magnet disk having a diameter of at least 4 cm is preferably used.

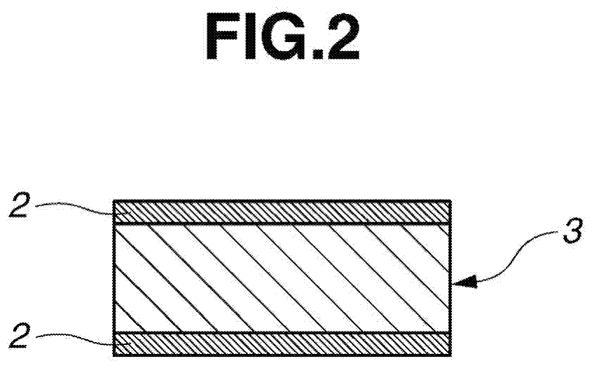

First, as shown in FIG. 2, a green resin compact 3 of sheet shape is formed from the resin composition prepared above. At least the top of the resin compact 3 is preferably covered with a cover 2. More preferably the resin compact 3 is sandwiched between the covers 2 as shown in FIG. 2. It is unfavorable that the resin compact is exposed without covering. This is because application of ultrasonic vibration is difficult, or ultrasonic vibration ruffles the resin compact surface to render its thickness non-uniform. The cover material used herein is preferably selected from resin films and non-ferromagnetic metal plates. Suitable resin films include polyethylene terephthalate (PET) films, polyethylene films, polytetrafluoroethylene (PTFE) films, and polytrifluorochloroethylene (PCTFE) films. Suitable non-ferromagnetic metal plates include aluminum plates, nonmagnetic stainless steel plates, copper plates, and titanium plates. Of these, PET films are preferred for handling and cost. At least one surface of the cover may be treated to impart release properties. The cover preferably has a thickness of up to 2 mm. As long as the cover thickness is up to 2 mm, ultrasonic vibration is fully conveyed to the center of the resin compact.

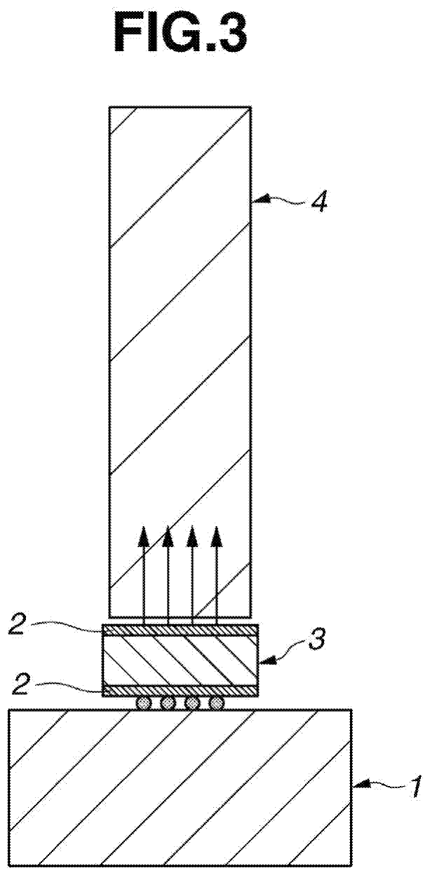

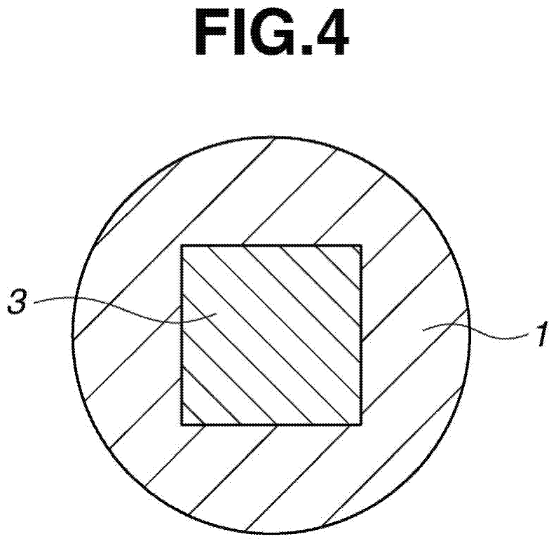

FIG. 3 is a schematic elevational view for illustrating the configuration of an orientation apparatus used in one embodiment of the present invention. FIG. 4 is a schematic top view of the apparatus. In FIGS. 3 and 4, a bulk superconductor magnet 1 is disposed below the resin compact 3 so as to apply a magnetic field across a part of the resin compact 3. An ultrasonic transducer 4 is disposed above the resin compact 3 so as to apply vibration to the resin compact 3.

The bulk superconductor magnet 1 creates and applies a magnetic field across a part of the resin compact 3 prepared above. In view of the magnetic field strength, the distance between the resin compact 3 and the bulk superconductor magnet 1 is preferably as short as possible. Then the ultrasonic transducer 4 produces and applies vibration, typically ultrasonic vibration to the resin compact 3 on the bulk superconductor magnet 1.

Suitable types of vibration used herein include vibration by hammering, vibration by pneumatic transducer, sonic vibration, ultrasonic vibration, and pneumatic vibration. Of these, sonic vibration at a frequency of higher than 5,000 Hz is preferred; ultrasonic vibration at a frequency of at least 20 kHz is more preferred for availability of a transducer and possible orientation in thin film form.

Application of vibration by the ultrasonic transducer may be performed across the resin compact while the compact is heated. The step of magnetic field orientation may be conducted plural times and at different positions.

Thereafter, the resin compact having fibers aligned is then reaction cured into a resin sheet having controlled anisotropy of thermal conductivity.

In the method of impregnating a bundle or cloth of carbon fibers with a gel-like resin and slicing the impregnated product, a resin sheet is preferably prepared by impregnating a bundle of fibers with a resin and slicing the impregnated bundle. Specifically, there are furnished carbon fibers in yarn form having an axial thermal conductivity of at least 100 W/mK. The fibers are bundled with their axis aligned. The fiber bundle is impregnated with a liquid silicone gel, obtaining a resin compact (bundle) having carbon fibers aligned or oriented in one direction. Thereafter, the resin compact is cured and thinly sliced by a cutter along a plane perpendicular to the axis of carbon fibers in the resin compact, obtaining a resin sheet.

The heat-conductive sheet thus obtained preferably has a surface tack of at least No. 4 as measured by a ball tack test using an inclination board of angle 30°. In view of thermal resistance, a surface tack of at least No. 6 is more preferred. It is also preferred in view of reliability that after 1,000 cycles of a thermal cycling test of holding at −55° C. for 30 minutes and heating at 150° C. for 30 minutes, the heat-conductive sheet has a surface tack of at least No. 4 as measured by the ball tack test. Notably, the ball tack test using an inclination board of angle 30° is performed according to JIS Z-0237: 2009.

Also preferably the heat-conductive sheet has a tensile strain (i.e., percent elongation at break in a tensile test) of at least 100%. In view of reliability, a tensile strain of at least 150% is more preferred. Notably, the tensile strain is measured at room temperature (25° C.) by a tensile test using a sheet of 1 cm×3 cm according to JIS K-7161-1: 2014.

The heat-conductive sheet should have a penetration of at least 30, preferably at least 40 in view of thermal resistance. The penetration of a heat-conductive sheet is measured by the same method as described above for the penetration of a cured product of component (B).

It is also preferable in view of reliability that after 1,000 cycles of a thermal cycling test of holding at −55° C. for 30 minutes and heating at 150° C. for 30 minutes, the heat-conductive sheet has a penetration corresponding to 80 to 120% of the initial value before the test.

The heat-conductive sheet preferably has a thermal conductivity of at least 5 W/mK, more preferably at least 10 W/mK in view of thermal resistance.

As used herein, the thermal conductivity of a heat-conductive sheet refers to a thermal conductivity of a resin sheet as measured in thickness direction by the laser flash method.

### EXAMPLES

Examples of the invention are given below by way of illustration and not by way of limitation. In Examples, the viscosity is measured at 25° C. by a rotational viscometer according to JIS K-7117-1: 1999. All parts are by weight.

A disk of Gd—Ba—Cu—O composition having a diameter of 6 cm was furnished and magnetized by a superconducting coil magnet of 6.5 T so that the disk might have a magnetic flux density of 4.5 T at the center, 3 T at a radius 1 cm from the center, 2 Tat a radius 2 cm from the center, 1 T at a radius 2.5 cm from the center, and 0.1 T or less at a radius 3 cm from the center, which was used as a bulk superconductor magnet. An ultrasonic transducer having an oscillation frequency of 20 kHz and a terminal diameter of 36 mm was used.

### Example 1

A resin composition was prepared by blending 100 parts of an addition cure type thermosetting liquid silicone gel (KJR-9017, Shin-Etsu Chemical Co., Ltd., viscosity: 1.0 Pa·s, penetration: 65) with 100 parts of carbon fibers having an average length of 200 μm and an axial thermal conductivity of 900 W/mK. A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Example 2

A resin composition was prepared by blending 100 parts of an addition cure type thermosetting liquid silicone gel (KJR-9017, Shin-Etsu Chemical Co., Ltd., viscosity: 1.0 Pa·s, penetration: 65) with 100 parts of carbon fibers having an average length of 200 μm and an axial thermal conductivity of 900 W/mK. A green resin compact was formed by applying the resin composition onto a release PET film of 100 μM thick over a region of 3 cm×3 cm to a thickness of 0.5 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Example 3

A resin composition was prepared by blending 100 parts of an addition cure type thermosetting liquid silicone gel (KJR-9017, Shin-Etsu Chemical Co., Ltd., viscosity: 1.0 Pa·s, penetration: 65) with 150 parts of carbon fibers having an average length of 200 μm and an axial thermal conductivity of 900 W/mK. A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Example 4

A resin composition was prepared by blending 100 parts of an addition cure type thermosetting liquid silicone gel (KJR-9017, Shin-Etsu Chemical Co., Ltd., viscosity: 1.0 Pa·s, penetration: 65) with 150 parts of carbon fibers having an average length of 200 μm and an axial thermal conductivity of 900 W/mK. A green resin compact was formed by applying the resin composition onto a release PET film of 100 μm thick over a region of 3 cm×3 cm to a thickness of 0.5 mm, covering the applied resin composition with an upper PET film of 100 μM thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Example 5

A resin composition was prepared by blending 100 parts of an addition cure type thermosetting liquid silicone gel (KE-1062, Shin-Etsu Chemical Co., Ltd., viscosity: 0.7 Pa·s, penetration: 40) with 100 parts of carbon fibers having an average length of 200 μm and an axial thermal conductivity of 900 W/mK. A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Example 6

A resin composition was prepared by blending 100 parts of an addition cure type thermosetting liquid silicone gel (KE-1062, Shin-Etsu Chemical Co., Ltd., viscosity: 0.7 Pa·s, penetration: 40) with 150 parts of carbon fibers having an average length of 200 μm and an axial thermal conductivity of 900 W/mK. A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Example 7

A bundle of carbon fibers in yarn form having an axial thermal conductivity of 500 W/mK with their axis aligned, 1,000 parts, was impregnated with 3,000 parts of an addition cure type thermosetting liquid silicone gel (KJR-9017, Shin-Etsu Chemical Co., Ltd., viscosity: 1.0 Pa·s, penetration: 65), obtaining a green resin compact having carbon fibers oriented in one direction. The resin compact was cured. While cooling with liquid nitrogen, the cured resin compact was thinly sliced by a cutter along a plane perpendicular to the axis of carbon fibers in the resin compact. There was obtained a resin sheet of 3 cm×3 cm×1 mm (thick).

### Comparative Example 1

A resin composition was prepared by blending 100 parts of an addition cure type thermosetting liquid silicone gel (KJR-9017, Shin-Etsu Chemical Co., Ltd., viscosity: 1.0 Pa·s, penetration: 65) with 200 parts of spherical alumina (GA-20H/53C, D₅₀=20 μm, Admatechs Co., Ltd.) and 40 parts of spherical alumina (AO-41R, D₅₀=3 Admatechs Co., Ltd.). A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. The resin compact was then cured into a resin sheet.

### Comparative Example 2

A resin composition was prepared by blending 100 parts of an addition cure type thermosetting liquid silicone gel (KJR-9017, Shin-Etsu Chemical Co., Ltd., viscosity: 1.0 Pa·s, penetration: 65) with 500 parts of spherical alumina (GA-20H/53C, D₅₀=20 μm, Admatechs Co., Ltd.) and 100 parts of spherical alumina (AO-41R, D₅₀=3 μm, Admatechs Co., Ltd.). A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking. The resin compact was then cured into a resin sheet.

### Comparative Example 3

A resin composition was prepared by blending 100 parts of an addition cure type thermosetting liquid silicone gel (KE-1062, Shin-Etsu Chemical Co., Ltd., viscosity: 0.7 Pa·s, penetration: 40) with 200 parts of spherical alumina (GA-20H/53C, D₅₀=20 μm, Admatechs Co., Ltd.) and 40 parts of spherical alumina (AO-41R, D₅₀=3 Admatechs Co., Ltd.). A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Comparative Example 4

A resin composition was prepared by blending 100 parts of an addition cure type thermosetting liquid silicone gel (KE-1062, Shin-Etsu Chemical Co., Ltd., viscosity: 0.7 Pa·s, penetration: 40) with 500 parts of spherical alumina (GA-20H/53C, D₅₀=20 μm, Admatechs Co., Ltd.) and 100 parts of spherical alumina (AO-41R, D₅₀=3 μm, Admatechs Co., Ltd.). A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. The resin compact was then cured into a resin sheet.

### Comparative Example 5

A resin composition was prepared by blending 100 parts of an addition cure type thermosetting liquid silicone rubber (X-35-033-4C, Shin-Etsu Chemical Co., Ltd., Shore D hardness: 20, viscosity: 0.4 Pa·s, penetration: <1) with 100 parts of carbon fibers having an average length of 200 μm and an axial thermal conductivity of 900 W/mK. A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Comparative Example 6

A resin composition was prepared by blending 100 parts of an addition cure type thermosetting liquid silicone rubber (X-35-033-4C, Shin-Etsu Chemical Co., Ltd., Shore D hardness: 20, viscosity: 0.4 Pa·s, penetration: <1) with 150 parts of carbon fibers having an average length of 200 μm and an axial thermal conductivity of 900 W/mK. A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet.

### Comparative Example 7

A resin composition was prepared by blending 100 parts of an addition cure type thermosetting liquid silicone rubber (X-35-033-4C, Shin-Etsu Chemical Co., Ltd., Shore D hardness: 20, viscosity: 0.4 Pa·s, penetration: <1) with 150 parts of carbon fibers having an average length of 200 μm and an axial thermal conductivity of 900 W/mK. A green resin compact was formed by applying the resin composition onto a release PET film of 100 μm thick over a region of 3 cm×3 cm to a thickness of 1 mm, covering the applied resin composition with an upper PET film of 100 μm thick, and sealing the periphery with a double-sided adhesive tape for preventing the resin from leaking out. Ultrasonic vibration was applied to the resin compact on the magnet from above the upper film at the central portion of the magnet. The resin compact was then cured into a resin sheet. Using a silicone gel (KJR-9017, Shin-Etsu Chemical Co., Ltd., viscosity: 1.0 Pa·s, penetration: 65), an adhesive layer of 50 μm thick was formed on opposite surfaces of the resin sheet.

The resin sheets in Examples 1 to 7 and Comparative Examples 1 to 7 were measured for the following properties. Also the resin sheets were subjected to 1,000 cycles of a thermal cycling test (TCT) of holding at −55° C. for 30 minutes and heating at 150° C. for 30 minutes before they were similarly measured for the properties. The results are shown in Table 1 (Examples) and Table 2 (Comparative Examples).

### Thermal Conductivity

A thermal conductivity was determined by punching the resin sheet into a test disk of diameter 13 mm, and analyzing it by the laser flash method according to JIS R-1611: 2010.

### Penetration

A penetration was measured by the consistency test according to JIS K-2220: 2013 using a ¼ cone under a total load of 9.38 g.

### Ball Tack Test

A ball tack was measured by the test method according to JIS Z-0237: 2009. The inclination angle was 30°.

### Thermal Resistance

The thermal resistance of the resin sheet was measured according to ASTM-D5470 under a load of 0.3 MPa.

### Tensile Strain

The tensile strain of a resin sheet strip of 1 cm×3 cm was measured at room temperature (25° C.) by the tensile test according to JIS-K-7161-1: 2014.

TABLE 1

| | | | Example | | | | | | |
|---|---|---|---|---|---|---|---|---|---|
| Component (pbw) | | | 1 | 2 | 3 | 4 | 5 | 6 | 7 |
| Resin | Carbon | 200 μm, 900 | 100 | 100 | 150 | 150 | 100 | 150 | 0 |
| composition | fiber | W/mK | | | | | | | |
| | | in yarn form, | 0 | 0 | 0 | 0 | 0 | 0 | 1,000 |
| | | 500 W/mK | | | | | | | |
| | Alumina | GA-20H/53C | 0 | 0 | 0 | 0 | 0 | 0 | 0 |
| | | AO-41R | 0 | 0 | 0 | 0 | 0 | 0 | 0 |
| | Resin | KJR-9017 | 100 | 100 | 100 | 100 | 0 | 0 | 3,000 |
| | | KE-1062 | 0 | 0 | 0 | 0 | 100 | 100 | 0 |
| | | X-35-033-4C | 0 | 0 | 0 | 0 | 0 | 0 | 0 |

| | | | | | | | |
|---|---|---|---|---|---|---|---|
| Thickness (mm) | 1.0 | 0.5 | 1.0 | 0.5 | 1.0 | 1.0 | 1.0 |
| Orientation | oriented | oriented | oriented | oriented | oriented | oriented | oriented |
| | under | under | under | under | under | under | as fiber |
| | magnetic | magnetic | magnetic | magnetic | magnetic | magnetic | bundle |
| | field | field | field | field | field | field | |
| Adhesive layer | nil | nil | nil | nil | nil | nil | nil |
| Thermal conductivity (W/mK) | 10.9 | 9.0 | 12.1 | 10.4 | 10.7 | 9.1 | 55.0 |
| Thermal resistance (K-mm²/W) | 52 | 38 | 43 | 36 | 54 | 41 | 35 |
| Thermal resistanceafter 1,000 cycles | 53 | 41 | 45 | 38 | 56 | 43 | 38 |
| of TCT (K-mm²/W) | | | | | | | |
| Ball tack test (ball No.) | No. 8 | No. 8 | No. 6 | No. 6 | No. 4 | No. 4 | No. 8 |
| Ball tack test after 1,000 cycles of | No. 8 | No. 8 | No. 5 | No. 5 | No. 4 | No. 4 | No. 8 |
| TCT (ball No.) | | | | | | | |
| Elongation at break (%) | 200 | 200 | 160 | 160 | 160 | 130 | 150 |
| Penetration | 55 | 55 | 53 | 53 | 40 | 40 | 55 |
| Penetration after 1,000 cycles of TCT | 53 | 53 | 51 | 51 | 38 | 38 | 52 |

Note:
In Examples 1 to 7, all (100 wt %) carbon fibers in the resin composition are oriented in thickness direction of the resin compact or resin sheet.

TABLE 2

| | | | Comparative Example | | | | | | |
|---|---|---|---|---|---|---|---|---|---|
| Component (pbw) | | | 1 | 2 | 3 | 4 | 5 | 6 | 7 |
| Resin | Carbon | 200 μm, 900 | 0 | 0 | 0 | 0 | 100 | 150 | 150 |
| composition | fiber | W/mK | | | | | | | |
| | | in yarn form, | 0 | 0 | 0 | 0 | 0 | 0 | 0 |
| | | 500 W/mK | | | | | | | |
| | Alumina | GA-20H/53C | 200 | 500 | 200 | 500 | 0 | 0 | 0 |
| | | AO-41R | 40 | 100 | 40 | 100 | 0 | 0 | 0 |
| | Resin | KJR-9017 | 100 | 100 | 0 | 0 | 0 | 0 | 0 |
| | | KE-1062 | 0 | 0 | 100 | 100 | 0 | 0 | 0 |
| | | X-35-033-4C | 0 | 0 | 0 | 0 | 100 | 100 | 100 |

| | | | | | | | |
|---|---|---|---|---|---|---|---|
| Thickness (mm) | 1.0 | 1.0 | 1.0 | 1.0 | 1.0 | 1.0 | 1.0 |
| Orientation | no | no | no | no | oriented | oriented | oriented |
| | | | | | under | under | under |
| | | | | | magnetic | magnetic | magnetic |
| | | | | | field | field | field |
| Adhesive layer | nil | nil | nil | nil | nil | nil | attached |
| Thermal conductivity (W/mK) | 1.6 | 3.0 | 1.5 | 2.8 | 11.2 | 12.4 | 10.2 |
| Thermal resistance (K-mm²/W) | 167 | 152 | 173 | 167 | 232 | 199 | 356 |
| Thermal resistance after 1,000 cycles | 194 | 190 | 198 | 187 | 245 | 203 | 342 |
| of TCT (K-mm²/W) | | | | | | | |
| Ball tack test (ball No.) | No. 2 | no tack | No. 3 | no tack | no tack | no tack | No. 8 |
| Ball tack test after 1,000 cycles of | No. 2 | no tack | No. 3 | no tack | no tack | no tack | No. 8 |
| TCT (ball No.) | | | | | | | |
| Elongation at break (%) | 80 | 40 | 60 | 30 | 1.6 | 1.5 | 1.5 |
| Penetration | 30 | 25 | 38 | 38 | 0.0 | 0.0 | 0.0 |
| Penetration after 1,000 cycles of TCT | 28 | 18 | 36 | 31 | 0.0 | 0.0 | 0.0 |

As seen from Tables 1 and 2, the heat-conductive sheets of Examples 1 to 7 have high adhesiveness, high thermal conductivity, and low thermal resistance and are useful as heat-dissipating resin. The resin sheets of fiber oriented structure in Examples 1 to 6 (Table 1) maintain high thermal conductivity, adhesiveness and penetration. After the thermal cycling test, the thermal resistance is kept low and other properties are little declined.

By contrast, the resin sheets of Comparative Examples 1 to 4 (Table 2) which are heavily loaded with alumina have rather poor adhesiveness and penetration and substantially lose properties after the thermal cycling test. This is because the resin sheet of a non-oriented structure must be heavily loaded with fillers, which detract from such properties. The resin sheets of Comparative Examples 5 and 6 (Table 2) using a non-tacky silicone rubber as the thermosetting organopolysiloxane composition (B) have a high interfacial resistance and hence, a high thermal resistance despite the oriented structure. The assembly of Comparative Example 7 (Table 2) having adhesive layers attached to the surfaces of a resin sheet shows a substantial increase of thermal resistance.

Japanese Patent Application No. 2019-077929 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. An anisotropic heat-conductive sheet having self-adhesiveness, comprising at least one heat-conductive layer of a cured product of a resin composition comprising (A) a fibrous heat-conductive filler and (B) a thermosetting organopolysiloxane composition,
the heat-conductive sheet having a penetration of at least 30.

2. The anisotropic heat-conductive sheet of claim 1 wherein all or some fibers of the heat-conductive filler (A) are oriented in one direction in the heat-conductive sheet.

3. The anisotropic heat-conductive sheet of claim 2 wherein fibers of the heat-conductive filler (A) are oriented in thickness direction of the heat-conductive sheet.

4. The anisotropic heat-conductive sheet of claim 1 wherein the thermosetting organopolysiloxane composition (B) is an addition reaction curable organopolysiloxane composition comprising:
(B-1) an organopolysiloxane having at least two alkenyl groups per molecule,
(B-2) an organohydrogenpolysiloxane having at least two silicon-bonded hydrogen atoms per molecule, and
(B-3) a platinum-based catalyst.

5. The anisotropic heat-conductive sheet of claim 1, which after 1,000 cycles of a thermal cycling test of holding at −55° C. for 30 minutes and heating at 150° C. for 30 minutes, has a penetration corresponding to 80 to 120% of the initial penetration of the sheet before the cycling test.

6. The anisotropic heat-conductive sheet of claim 1, which has a surface tack of at least No. 4 in a ball tack test using an inclination board of angle 30° according to JIS Z-0237: 2009.

7. The anisotropic heat-conductive sheet of claim 1, which after 1,000 cycles of a thermal cycling test of holding at −55° C. for 30 minutes and heating at 150° C. for 30 minutes, has a surface tack of at least No. 4 in a ball tack test using an inclination board of angle 30° according to JIS Z-0237: 2009.
